(19) United States
(12) Patent Application Publication
(10) Pub. No.: US 2009/0283905 A1
(43) Pub. Date: Nov. 19, 2009

(54) CONDUCTIVE STRUCTURE OF A CHIP

(76) Inventors: Hsiang-Ming HUANG, (US); An-Hong Liu, (US); Yi-Chang Lee, (US); Hao-Yin Tsai, (US); Shu-Ching Ho, (US)

Correspondence Address: Muncy, Geissler, Olds & Lowe, PLLC, P.O. BOX 1364, FAIRFAX, VA, 22038-1364, US

(21) Appl. No.: 12/262,766

(22) Filed: Oct. 31, 2008

(30) Foreign Application Priority Data
May 19, 2008 (TW) 097109740

(51) Int. Cl. H01L 23/488

(52) U.S. Cl. 257/737; 257/E23.023

(57) ABSTRACT

A conductive structure of a chip is provided. The conductive structure comprises a ground layer, a dielectric layer, a redistribution layer, an under bump metal and a solder bump. The ground layer electrically connects to the ground pad of the chip, while the dielectric layer overlays the ground layer. Thus, the conductive layer can result in impedance matching, and the packaged chip is adapted to transmit a high frequency signal.

This application claims priority to Taiwan Patent Application No. 097109740 filed on Mar. 19, 2008, the disclosures of which are incorporated herein by reference in their entirety.

### CROSS-REFERENCES TO RELATED APPLICATIONS

Not applicable.

### BACKGROUND OF THE INVENTION

1. Field of the Invention

The present invention provides the conductive structure of a chip capable of achieving impedance matching on the chip when transmitting high frequency signals.

2. Descriptions of the Related Art

With the advancement of integrated circuit (IC) technologies. ICs have become increasingly complex in design, while the various components thereof have become smaller. Once the fabrication of an IC is completed on a wafer, the wafer is transferred to a packaging facility for subsequent dicing and packaging. The quality of the packaging process impacts the operational performance of the packaged chip.

As shown in FIGS. 1A through 1G. a conventional chip package conductive structure and a manufacturing process thereof are depicted therein. As depicted in FIG. 1A, the chip 11 is prefabricated with a pad 131 and a first passivation layer 13, in which the first passivation layer 13 is formed on the surface of the chip 11 and partially exposes the pad 131 therethrough. Then, depending on the design requirements, the first under bump metal (UBM) 133 is formed on the partially exposed pad 131 as shown in FIG. 1B. The first UBM 133 is made of a material selected from a group consisting of Cr, Ti, Ni, Cu, or alloys thereof.

Next, as shown in FIG. 1C. a patterned redistribution layer (RDL) 15 is formed through a photolithographic process to overlay the first UBM 133 and partially overlay the first passivation layer 13. The RDL 15 is made of a conductive material including Al or Cu and is electrically connected to the first UBM 133. With the RDL 15, the bumps that are subsequently formed may be electrically connected to the pad 131 without being limited by the location of the pad 131. Hence, the bumps may be re-arranged according to the actual requirements with enhanced flexibility. Subsequently, as shown in FIG. 1D, a second passivation layer 17 is extensively formed to overlay the RDL 15 and the first passivation layer 13 and is patterned through a lithographic process to partially expose the RDL 15 at appropriate locations.

Next, as shown in FIG. 1E. a second UBM 135 is formed on the partially exposed RDL 15. Then, as shown in FIG. 1F. a bump 19 is solder plated or a solder ball is implanted onto the second UBM 135 to electrically connect with the second UBM 135. Finally, the bump 19 shown in FIG. 1F may be reflowed to obtain a ball bump 19 as shown in FIG. 1G.

However, as demands on products are increasingly heightened and associated technologies advance, the electronic components or chips are working at ever higher operating frequencies, and often work with high frequency signals particularly when applied to a radio frequency (RF) IC chip or an optical reading chip. Unfortunately, when a conventional package conductive structure is applied to a high frequency circuit, the impedance mismatch of the conductive structure causes some signals to be reflected when being transmitted from the chip 11 to the package conductive structure, resulting in the distortion of signals.

In view of this, it is increasingly important to provide a package conductive structure capable of achieving impedance matching when a chip works at a high frequency.

### SUMMARY OF THE INVENTION

An objective of this invention is to provide a conductive structure of a chip, which comprises a redistribution layer (RDL), an under bump metal (UBM), a bump, a ground layer and a dielectric layer. The redistribution layer is formed on the chip, and has a first conductive area and a second conductive area. The first conductive area is adapted to be electrically connected to the chip. The UBM is formed on and electrically connected to the second conductive area of the redistribution layer; and the bump is formed on and electrically connected to the UBM.

By additionally disposing the ground layer and the dielectric layer between the conventional chip and the redistribution layer, an impedance matching effect is achieved between the conductive structure and the chip, which is particularly favorable for transmitting high frequency signals.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIGS. 1A to 1G are schematic views of a chip package conductive structure of the prior art; and

FIGS. 2A to 2H are schematic views of a chip package conductive structure according to the preferred embodiment of this invention.

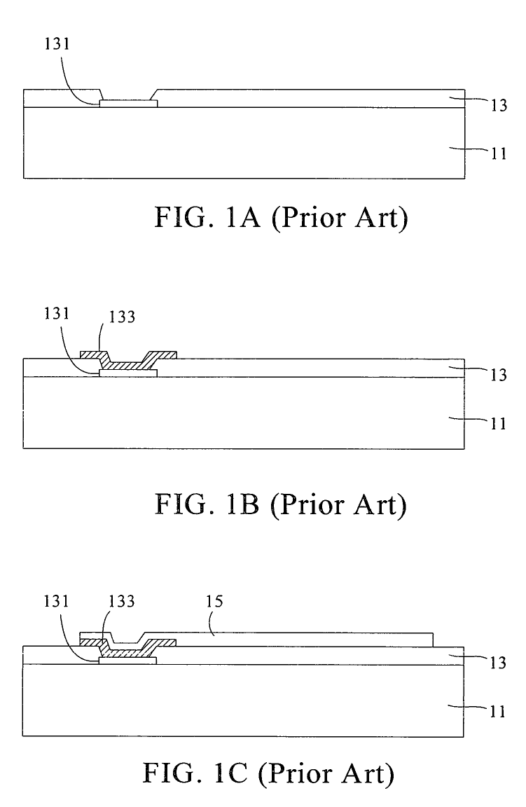

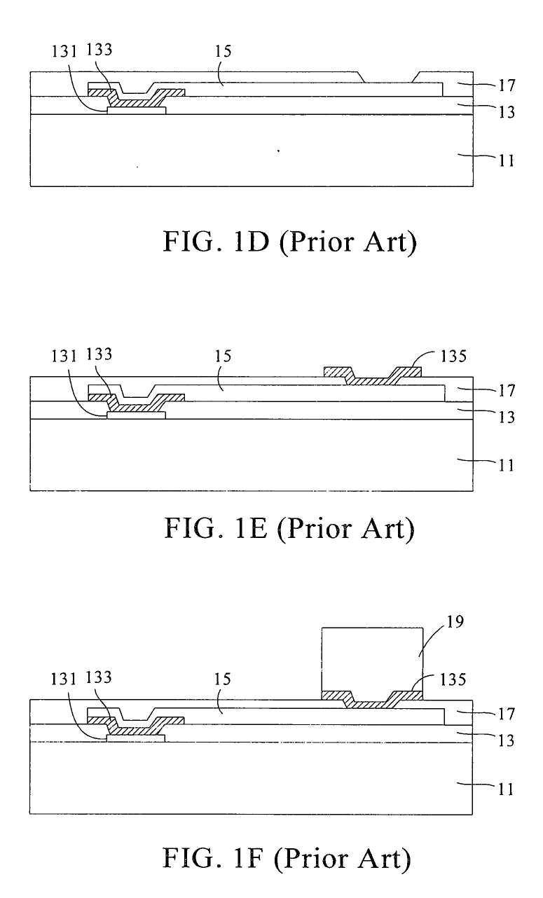

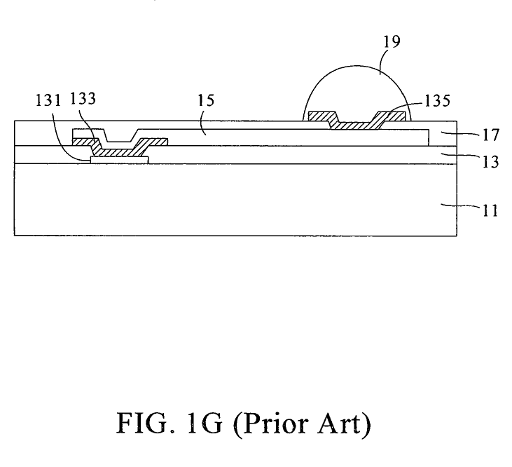

### DESCRIPTION OF THE PREFERRED EMBODIMENT

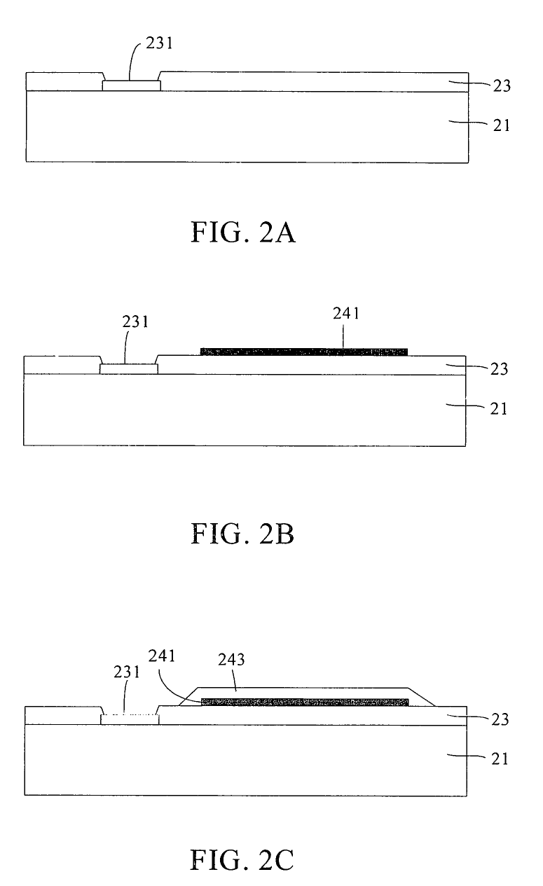

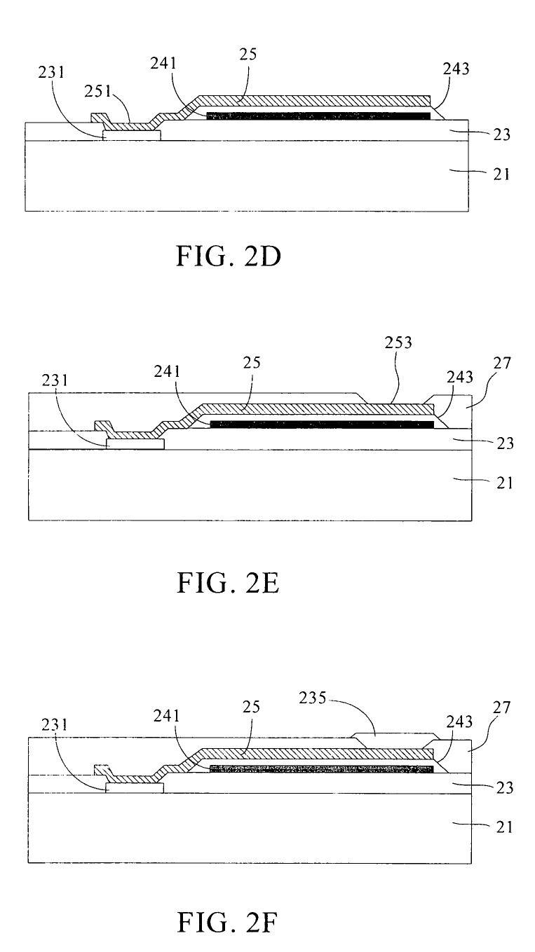

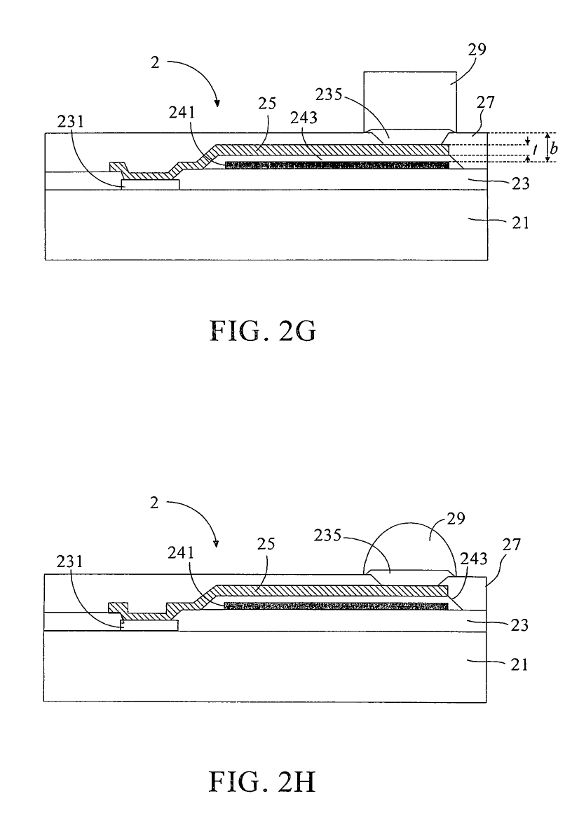

FIGS. 2G and 2H are schematic views of a conductive structure 2 of a chip 21 according to this invention. The conductive structure 2 comprises a ground layer 241, a dielectric layer 243, a redistribution layer 25, a UBM 235 and a bump 29. To disclose the structure of this invention more clearly, the preferred embodiment of this invention will be described in detail hereinafter with reference to FIGS. 2A to 2H in sequence.

First, as shown in FIG. 2A, when the chip 21 is initially formed, the chip 21 at least comprises an input/output pad 231 and a first passivation layer 23 on the surface thereof. It should be noted that, as can be readily appreciated by those of ordinary skill in the art, although only a single input/output pad 231 is illustrated in cross-sectional side views in the attached drawings of this invention, the surface of the chip 21 actually has a plurality of pads distributed thereon, which further comprises a ground pad (not shown) in addition to the input/output pad 231. The input/output pad 231 is made of Al or Cu, and the first protection layer 23 partially overlays the input/output pad 231 to partially expose the input/output pad 231.

As shown in FIG. 2B, a ground layer 241 is partially formed on the first passivation layer 23 of the chip 21 in this invention. The ground layer 241 is adapted to be electrically connected with a ground pad of the chip 21 so that a potential of the ground layer 241 and the potential of the ground pad are equal, wherein both potentials are relative to the reference potential outside the conductive structure 2.

Next, as shown in FIG. 2C, the dielectric layer 243 is formed to overlay the ground layer 241. The dielectric layer 243 is preferably made of polyimide (PI), Benzocyclobutene (BCB), or SU-8 photoresist. However, other materials may also be used instead by those of ordinary skill in the art, and no limitation is made herein.

Next, as shown in FIG. 2D, the redistribution layer 25 is formed on the chip 21. More specifically, the redistribution layer 25 overlays the dielectric layer 243 and is electrically connected to the input/output pad 231. To explain this invention more clearly, the redistribution layer 25 may be defined to have a first conductive area 251, through which the distribution layer 25 is electrically connected to the input/output pad 231 of the chip 21. Next, as shown in FIG. 2E, the second passivation layer 27 is formed to overlay the distribution layer 25 and patterned through a photolithographic process to partially expose the second conductive area 253 of the redistribution layer 25. The second passivation layer 27 should have substantially the same dielectric constant εᵣ as that of the dielectric layer 243. For example, the second protection layer 27 is also made of polyimide (PI), Benzocyclobutene (BCB), or SU-8 photoresist.

Subsequently, as shown in FIG. 2F, the UBM 235 is formed on and electrically connected to the second conductive area 253 of the redistribution layer 25. The UBM 235 in this embodiment may be formed using various manners. For example, there may be a sputtering layer formed through a sputtering process, or an electroless plating layer formed through an electroless plating process. Forming the UBM 235 through a sputtering process has been known as the conventional practice and thus will not be further described herein. On the other hand, if using an electroless plating process, the UBM 235 may be made of Ni or Au, and appropriate processes that may be employed will readily occur to those or ordinary skill in the art and no limitation is made herein.

Finally, as shown in FIG. 2G, the bump 29 is formed on the UBM 235 to be electrically connected thereto. A reflow process may be further performed on the bump 29 to form a ball bump 29, as shown in FIG. 2H.

Also, in reference to FIG. 2G, a description will be made for characteristic impedance Z₀ formed in this invention. The characteristic impedance Z₀ of the conductive structure 2 is correlated with a thickness b defined by the dielectric layer 243 and the second passivation layer 27, a line width w (not shown) of the redistribution layer 25, a thickness t of the redistribution layer 25, and the dielectric constant εᵣ of the dielectric layer 243 and the second passivation layer 27 in the following relationship:

$${Z}_{0} = \frac{60}{\sqrt{{ɛ}_{r}}} ln ( \frac{1.9 b}{0.8 w + t} )$$

For example, if the second passivation layer 27 and the dielectric layer 243 are made of the same material, e.g., polyimide with a dielectric constant εᵣ of 3.2, and a characteristic impedance Z₀ of 50Ω is desired, the parameters b, w and t can be determined accordingly by substituting εᵣ=3.2 and Z₀=50 into the above relationship. Generally, the thickness t of the redistribution layer 25 has less impact on the transmission of high frequency signals, so once the materials used for the second passivation layer 27 and the dielectric layer 243 as well as the characteristic impedance Z₀ are determined, typically only the thickness b defined by the dielectric layer 243 and the second passivation layer 27 and the width w of the redistribution layer 25 remain to be designed. In other words, if the width w of the redistribution layer 25 increases, the thickness b defined by the dielectric layer 243 and the second passivation layer 27 shall be increased accordingly to substantially obtain the characteristic impedance Z₀ of 50Ω. With this characteristic impedance Z₀, a matching impedance of 50Ω can be achieved in the conductive structure 2 when transmitting a high frequency signal. It should be noted that the aforesaid values are only intended to illustrate a conductive structure capable of achieving an impedance matching effect, and those of ordinary skill in the art may design different dimensions in this manner. Furthermore, an impedance-matching conductive structure may also be designed by using different materials for the dielectric layer 243 and the passivation layer 27 respectively.

In summary, by additionally disposing the ground layer and the dielectric layer between the chip and the redistribution layer in the conductive structure of this invention, an impedance matching effect is achieved. This is particularly favorable for the transmission of high frequency signals and may remarkably reduce the signal distortion caused by signal reflection.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A conductive structure of a chip, comprising:
a redistribution layer (RDL) formed on the chip, the redistribution layer having a first conductive area and a second conductive area, wherein the redistribution layer electrically connects to the chip by the first conductive area thereof;
an under bump metal (UBM) formed on and electrically connected to the second conductive area of the redistribution layer;
a bump formed on and electrically connected to the UBM;
wherein the conductive structure further comprises a ground layer formed on the chip and a dielectric layer overlaying the ground layer, and the ground layer and the dielectric layer are disposed between the chip and the redistribution layer.

2. The conductive structure as claimed in claim 1, wherein the chip comprises a plurality of pads and a first passivation layer, the plurality of pads at least including an input/output pad and a ground pad, in which the ground layer is formed on the first passivation layer and electrically connected to the ground pad.

3. The conductive structure as claimed in claim 2, wherein the redistribution layer overlays the dielectric layer and electrically connects to the input/output pad of the chip at the first conductive area thereof.

4. The conductive structure as claimed in claim 3, further comprising a second passivation layer overlaying the redistribution layer, on which the second conductive area are partially exposed.

5. The conductive structure as claimed in claim 4, wherein the dielectric layer is made of one of polyimide (PI), Benzocyclobutene (BCB), and SU-8 photoresist.

6. The conductive structure as claimed in claim 5, wherein both of the second passivation layer and the dielectric layer are made of materials which have substantially a same dielectric constant.

7. The conductive structure as claimed in claim 6, wherein the second passivation layer is made of one of polyimide (PI), Benzocyclobutene (BCB), and SU-8 photoresist.

8. The conductive structure as claimed in claim 6, wherein a thickness defined by the dielectric layer and the second passivation layer, a width of the redistribution layer, a thickness of the redistribution layer, and the dielectric constant are all correspondingly configured such that the redistribution layer operatively forms an impedance matching when the conductive structure transmits a high frequency signal.

9. The conductive structure as claimed in claim 1, wherein the under bump metal is an electroless plating layer.

10. The conductive structure as claimed in claim 9, wherein the electroless plating layer is made of Ni and Au.

11. The conductive structure as claimed in claim 1, wherein the under bump metal is a sputtering layer.

12. The conductive structure as claimed in claim 2, wherein each of the pads is made of one of aluminum and copper.
